(19) United States
(12) Patent Application Publication
(10) Pub. No.: US 2015/0188088 A1
(43) Pub. Date: Jul. 2, 2015

(54) ORGANIC ELECTROLUMINESCENT ELEMENT, LIGHTING FIXTURE, AND METHOD FOR PREPARING ORGANIC ELECTROLUMINESCENT ELEMENT

(71) Applicant: PANASONIC INTELLECTUAL PROPERTY MANAGEMENT CO., LTD., Osaka (JP)

(72) Inventors: Hirofumi Kubota, Osaka (JP); Shin Okumura, Osaka (JP); Takuya Komoda, Hyogo (JP)

(73) Assignee: PANASONIC INTELLECTUAL PROPERTY MANAGEMENT CO., LTD., Osaka (JP)

(21) Appl. No.: 14/418,141

(22) PCT Filed: Sep. 10, 2013
(86) PCT No.: PCT/JP2013/005342

§ 371 Date: Jan. 29, 2015

(30) Foreign Application Priority Data
Sep. 11, 2012 (JP) 2012-199896

(51) Int. Cl. H01L 51/52; H01L 51/00; H01L 51/56

(52) U.S. Cl. CPC H01L 51/5268; H01L 51/56; H01L 51/5237; H01L 51/0096; H01L 51/0021; H01L 2251/5361

(57) ABSTRACT

An organic electroluminescent element according to the present invention includes a light transmissive substrate, a first electrode, an organic light-emitting layer, and second electrode. The first electrode is formed of a coating type conductive film. The organic electroluminescent element further includes a light scattering layer between the substrate and the first electrode and in contact with the first electrode. The light scattering layer is formed of an organic material and a surface of the light scattering layer being in contact with a surface of the first electrode is provided with a plurality of recesses.

### TECHNICAL FIELD

The present invention relates to an organic electroluminescent element, a lighting fixture, and a method for preparing organic electroluminescent element.

### BACKGROUND ART

Conventionally, an organic electroluminescent element (i.e., an organic light-emitting diode) is provided with a light scattering layer in order to improve light extraction efficiency of the organic electroluminescent element.

For example, Patent Literature 1 discloses the following four things. First of all, the literature discloses an organic electroluminescent element including a substrate, a first electrode, an organic layer including an organic light-emitting layer, and a second electrode. Secondly, on the substrate, formed is a fine uneven structure, which is formed of resin having a lower refractive index than that of the substrate. Thirdly, on the fine uneven structure, formed is a transparent layer, which is formed of resin having a high refractive index. Finally, the first electrode is formed on the transparent layer by a spattering method. In this case, an uneven interface is formed between the fine uneven structure and the transparent layer, and accordingly, light emitted from the organic light-emitting layer is scattered. Therefore, the light extraction efficiency improves.

However, the art disclosed in the Patent Literature 1 requires two processes of forming the fine uneven structure and forming the transparent layer. For this reason, it results in the complexity of the structure of the organic electroluminescent element and the complication of manufacturing process.

In addition, heat resistant temperatures of the fine uneven structure and the transparent layer are low since the fine uneven structure and the transparent layer are formed of resin. Therefore, reducing a deposition temperature is required in order to form the first electrode on the surface of the transparent layer by a vapor deposition such as a sputtering method. In this case, the issue is that power consumption increases as a drive voltage of the organic electroluminescent element is raised because of a high resistivity of the first electrode.

### CITATION LIST

### Patent Literature

Patent Literature 1: JP2011-48937A1

### SUMMARY OF THE INVENTION

### Problems to be Resolved by the Invention

The present invention has been made in the light of the above-mentioned problem, and it is an object thereof to provide: an organic electroluminescent element capable of improving light extraction efficiency, simplifying the structure, and decreasing power consumption; a lighting fixture including the organic electroluminescent element; and a method of manufacturing the organic electroluminescent element.

### Means of Solving the Problems

The organic electroluminescent element according to a 1st aspect includes a light transmissive substrate, a first electrode, an organic light-emitting layer, and a second electrode which are stacked in this order. The first electrode is a conductive film including conductive particles. The organic electroluminescent element further includes a light scattering layer between the substrate and the first electrode and in contact with the first electrode. The light scattering layer is provided in a surface thereof with a plurality of recesses. The surface of the light scattering layer is in contact with a surface of the first electrode.

As a 2nd aspect, in the 1st aspect, each of the recesses has a depth of 0.3 to 3.0 μm and an average width of 0.3 to 3.0 μm.

As a 3rd aspect, in the 1st and the 2nd aspects, the first electrode has an uneven surface on an opposite side of the first electrode from the light scattering layer.

The organic electroluminescent element according to a 4th aspect, in any one of the 1st to the 3rd aspects includes a conductive layer between the first electrode and the organic light-emitting layer and in contact with the first electrode, and a sheet resistance value of the conductive layer is equal to or less than that of the first electrode.

As a 5th aspect, in any one of the 1st to the 4th aspects, the first electrode contains at least one component selected from a conductive inorganic oxide, a metallic nano-material, and a conductive polymer, and the conductive layer contains a conductive inorganic oxide.

As a 6th aspect, in the 4th or 5th aspect, the first electrode and the conductive layer contain a common material.

A light fixture according to a 7th aspect, in any one of the 1st to the 6th aspects, includes the organic electroluminescent element.

A method of preparing an organic electroluminescent element according to an 8th aspect includes the organic electroluminescent element including a light transmissive substrate, a first electrode, an organic light-emitting layer, and a second electrode which are stacked in this order, and the organic electroluminescent element further including a light scattering layer between the substrate and the first electrode and in contact with the first electrode: the method including: a process of forming the light scattering layer, by molding an ultraviolet curable resin composition into a film, then forming the recesses in the resin composition by embossing the resin composition; and then curing the resin composition by an irradiation of ultraviolet rays; and a process of forming the first electrode, by applying a conductive material on a surface of the light scattering layer in which the recesses are formed, and then by curing the light scattering layer.

The method of preparing the organic electroluminescent element according to a 9th aspect includes forming a conductive layer on the first electrode by a vapor deposition, and a sheet resistance value of the conductive layer being equal to or less than that of the first electrode.

The method of preparing the organic electroluminescent element according to a 10th aspect, in the 9th aspect, further includes heating the conductive layer by an induction heating method.

The method of preparing the organic electroluminescent element according to an 11th aspect, in the 9th or 10th aspect, further includes forming the conductive layer by a sputtering method.

As the method of preparing the organic electroluminescent element according to a 12th aspect, in any one of the 8th or 11th aspect, the conductive material includes conductive particles.

### Effect of the Invention

The present invention can realize improving light extraction efficiency of an organic electroluminescent element, simplifying the structure, and decreasing the power consumption, by an easy way such as providing a light scattering layer between a substrate and a first electrode.

### BRIEF DESCRIPTION OF THE DRAWINGS

FIG. 1A is a cross-sectional view showing a process of manufacturing an organic electroluminescent element according to a first embodiment of the present invention.

FIG. 1B is a cross-sectional view showing a process of manufacturing the organic electroluminescent element according to the first embodiment of the present invention.

FIG. 1C is a cross-sectional view showing a process of manufacturing the organic electroluminescent element according to the first embodiment of the present invention.

FIG. 1D is a cross-sectional view showing a process of manufacturing the organic electroluminescent element according to the first embodiment of the present invention.

FIG. 1E is a cross-sectional view showing a process of manufacturing the organic electroluminescent element according to the first embodiment of the present invention.

FIG. 2A is a cross-sectional view showing a process of manufacturing an organic electroluminescent element according to a second embodiment of the present invention.

FIG. 2B is a cross-sectional view showing a process of manufacturing the organic electroluminescent element according to the second embodiment of the present invention.

FIG. 2C is a cross-sectional view showing a process of manufacturing the organic electroluminescent element according to the second embodiment of the present invention.

FIG. 3 is a cross-sectional view showing a light fixture including an organic electroluminescent element.

### EMBODIMENT FOR CARRYING OUT THE INVENTION

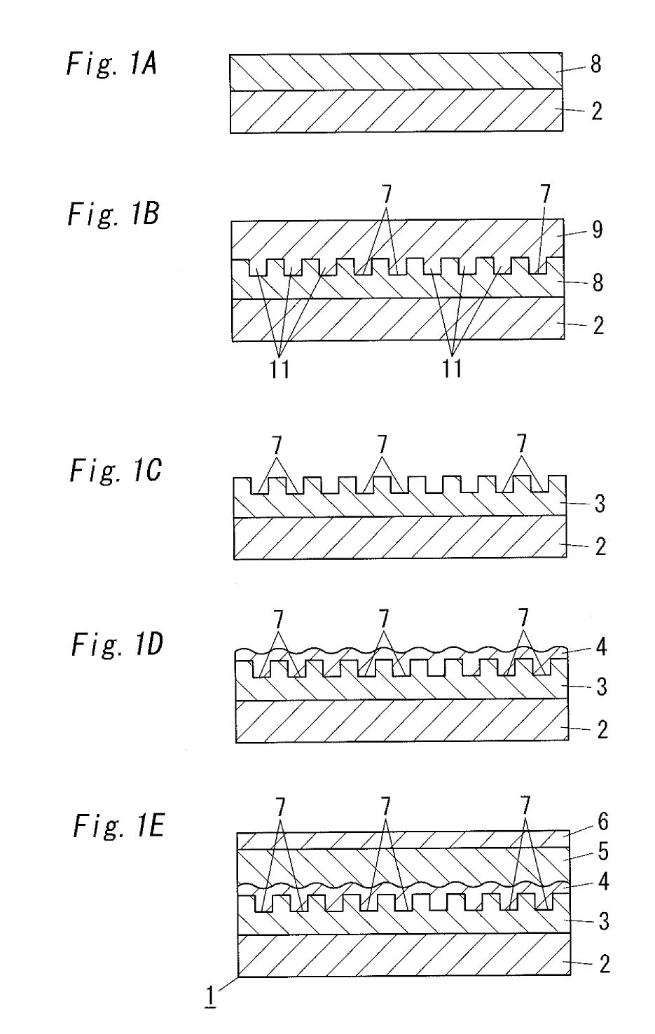

FIG. 1E schematically shows a structure of an organic electroluminescent element 1 (i.e., organic light-emitting diode) according to a first embodiment. The organic electroluminescent element 1 includes a light transmissive substrate 2, a first electrode 4, an organic light-emitting layer 5, and a second electrode 6 which are stacked in this order. Furthermore, a light scattering layer 3 is provided between the substrate 2 and the first electrode 4. The light scattering layer 3 is in contact with the first electrode 4. Namely, the substrate 2, the light scattering layer 3, the first electrode 4, the organic light-emitting layer 5 and the second electrode 6 are stacked in this order in the present embodiment. The substrate 2 and the light scattering layer 3 may not necessarily be in contact with each other directly, and the first electrode 4 and the organic light-emitting layer 5 may not necessarily be in contact with each other directly, and the organic light-emitting layer 5 and the second electrode 6 may not necessarily be in contact with each other directly, but the light scattering layer 3 and the first electrode 4 are directly in contact with each other.

The first electrode 4 mainly includes conductive particles. The first electrode 4 is preferably formed of a coating type conductive film. Moreover, the light scattering layer 3 is preferably formed of an organic material. A surface of the light scattering layer 3 being in contact with a surface of the first electrode 4 is provided with recesses 7.

The first electrode 4 performs a function as an electrode when the first electrode 4 includes the conductive particles and the conductive particles are electrically conducted with other.

An uneven interface is formed between the light scattering layer 3 and the first electrode 4, because the organic electroluminescent element 1 according to the present embodiment has the above-mentioned configuration. Therefore, when light from the organic light-emitting layer 5 is emitted to the outside through the substrate 2, the light is easily scattered on the interface between the light scattering layer 3 and the first electrode 4. This can realize improving light extraction efficiency from the organic electroluminescent element 1. Scattering of the light emitted from the organic electroluminescent element 1 gives less color difference between an emission color of light emitted from the organic electroluminescent element 1 in the front direction (i.e., a direction in which the components constituting the organic electroluminescent element 1 are stacked) and an emission color of light emitted from the element 1 in a direction angled with respect to the front direction. Therefore, even if the viewpoint position of an observer for the organic electroluminescent element 1 is changed, the observer has difficulties to recognize a change in an emission color of the emitted light. In other words, a view angle for the organic electroluminescent element 1 becomes wider.

As mentioned above, in the present embodiment, it is possible to improve light extraction efficiency from the organic electroluminescent element 1 by an easy configuration such as having the light scattering layer 3 between the substrate 2 and the first electrode 4.

Moreover, the complicated shaped light scattering layer 3 with the recesses 7 is easily formed by the light scattering layer 3 being formed of an organic material.

In addition, when the first electrode 4 is formed of the coating type conductive film, a restriction of forming the first electrode 4 by a vapor deposition such as a sputtering method is eliminated. In other words, when the first electrode 4 is deposited by a vapor deposition on the surface of the light scattering layer 3 made of the organic material, reducing a deposition temperature has to be made in order to retrain damage of the light scattering layer 3. With this result, the first electrode 4 has a high sheet resistance, thereby increasing electric power consumption of the organic electroluminescent element 1. On the other hand, in a case where the coating type conductive film is formed, reducing the deposition temperature is not required. Therefore, it is possible to suppress the electric power consumption of the organic electroluminescent element 1.

The details of the configuration of the organic electroluminescent element 1 according to the present embodiment and the method of preparing the same are described below.

The substrate 2 may be colorless or colored as long as the substrate 2 has a light transmitting property. Moreover, the substrate 2 may be clear or translucent. Examples of materials for the substrate 2 include: glass such as soda-lime glass and alkali-free glass; and plastic such as polyester, polyolefin, polyamide resin, epoxy resin, and fluorine-based resin. However there is no limitation on the material for the substrate 2. The shape of the substrate 2 may be a film-like shape or a plate-like shape.

The light scattering layer 3 is formed of an appropriate resin composition for example. In particular, the light scattering layer 3 is preferably formed of an ultraviolet curable resin composition, and the ultraviolet curable resin composition preferably includes resin having an acrylate type functional group. Known resin may be used as the above resin. Furthermore, it is preferable that the ultraviolet curable resin composition further includes a photopolymerization initiator.

In addition, the light scattering layer 3 may be formed of a thermosetting resin or a thermoplastics resin.

To form the light scattering layer 3, a coating film in an uncured state composed of the resin composition 8 is first formed by, for example, applying the resin composition 8 on the substrate 2, as shown in FIG. 1A. In this case, a coating method may be selected from a spin coating, a screen printing, a dip coating, a die coating, a cast coating, a spray coating, and a gravure coating, for example. Therefore, the resin composition 8 is formed into a coating film in the uncured state.

Then, as shown in FIG. 1B, the recesses 7 are formed by embossing the coating film in the uncured state composed of the resin composition 8. As an example of embossing, a nanoimprint method may be selected. In particular, a mold 9 is preferably used in embossing. The mold 9 is formed of transparent materials such as quartz. Projections 11 which respectively correspond to the recesses 7 of the light scattering layer 3 are formed on a surface of the mold 9. The light scattering layer 3 is formed by pressing the mold 9 against the coating film in the uncured state and then curing the coating film by an irradiation of ultraviolet rays. The recesses 7 are formed in the surface of the light scattering layer 3 by transcribing the shape of the mold 9.

Upon the irradiation of ultraviolet rays to the coating film in the uncured state, ultraviolet rays may be radiated to the coating film through the transparent substrate 2. Therefore, it can be easy to radiate ultraviolet rays to the whole of the coating film. In addition, the coating film may be irradiated by ultraviolet rays through the mold 9 if the mold 9 is formed of transparent materials. In this case, it can be easy to radiate ultraviolet rays to the whole of the coating film as well. Furthermore, it may be difficult to control the uneven structure of the coating film because of flow of the coating film, when the coating film in the uncured state is embossed. In such a case, the following steps may be carried out. The fluidity of the coating film may be reduced by temporarily curing (by half curing) the coating film with heat for example, followed that the coating film may be embossed and finally may be cured by ultraviolet rays.

The method of forming the light scattering layer 3 having the recesses 7 is not restricted to the above mentioned method. As examples of forming the light scattering layer 3, it may be formed from a resin composition having a thermosetting resin such as polyimide, polyamide-imide, epoxy, and polyurethane. In this case, for example, application of the resin composition on the substrate 2 may form the coating layer in the uncured state. The recesses 7 may be then formed by an imprint method or the like on the coating film, followed that the coating film may be formed as the light scattering layer 3 by heat curing. Moreover, lithography such as optical lithography or electron beam lithography may be accepted in order to form the recesses 7 in the surface of the light scattering layer 3.

The size of each of the recesses 7 in the surface of the light scattering layer 3 is set at appropriate dimension based on light scattering performance of the light scattering layer 3. It is preferable to set the size of each of the recesses 7 in order to especially improve the light scattering performance of the light scattering layer 3 as follows.

Preferably, the recesses 7 each have a depth of 0.3 to 3.0 μm.

In addition, the widths of all recesses 7 may be set at the same or different width each other. The improvement of the light scattering performance by the light scattering layer 3 and the improvement of the brightness of elements can be achieved, when the recesses 7 have widths different from each other. Preferably the recesses 7 each have a depth of 0.3 to 3.0 μm. In addition, preferably the recesses 7 have an average width of 0.2 to 1.2 μm. A width of each recess 7 is defined as the longest length of a plurality of straight lines, each of which is obtained by connecting any two points on an outline of the each recess 7 in a plan view. Moreover, the plan view is defined as viewing a surface of the light scattering layer 3 having the recesses 7 in a direction where the light scattering layer 3 and the substrate 2 are stacked.

Moreover, the recesses 7 may be set to be every spaced at the same or different distance. The light scattering performance by the light scattering layer 3 can be more improved, when the recesses 7 are every spaced at different distance. Preferably, the recesses 7 are spaced at a distance of 0.2 to 2.0 μm. In addition, preferably, the recesses 7 are averagely spaced at a distance of 0.3 to 1.0 μm. Moreover, the spacing of the recesses 7 is defined as a minimum distance between two adjacent recesses 7 in a plan view.

Preferably, a ratio of areas of the recesses 7 to an area of the light scattering layer 3 is in a range of 50% to 90% in a plan view.

The thickness of the light scattering layer 3 is not limited in particular. However, the thickest part of the light scattering layer 3 is preferably in a range of 2.0 to 5.0 μm. The thinnest part is preferably in a range of 0.5 to 2.0 μm.

The first electrode 4 is formed on the surface of the light scattering layer 3 after the light scattering layer 3 is formed, as shown in FIG. 1D. The first electrode 4 functions as an anode in the present embodiment. The anode in the organic electroluminescent element 1 is an electrode for injecting holes into the organic light-emitting layer 5.

The first electrode 4 is preferably formed of a coating type conductive film. The coating type conductive film is defined as a conductive film formed by coating conductive material having fluidity.

In the present embodiment, the conductive material preferably contains conductive particles. In this case, the first electrode 4 containing the conductive particles can be obtained. The shapes of the conductive particles are not limited in particular but may be particulate or fibrous.

The conductive material is not limited in particular. However, the conductive material preferably contains at least one component selected from conductive inorganic oxide, metallic nano-material and conductive polymer. In other words, the first electrode 4 preferably contains at least one component selected from the conductive inorganic oxide, metallic nano-material and conductive polymer.

In particular, it is preferable that the conductive material contains the conductive particles and the conductive particles contain at least one component selected from the conductive inorganic oxide, metallic nano-material and conductive polymer.

Examples of the conductive inorganic oxide include more than one component selected from ITO (indium-tin oxide), SnO₂, ZnO, IZO (indium-zinc oxide), and AZO (Aluminum-doped zinc-oxide) when the first electrode 4 containing the conductive inorganic oxide is formed. The conductive inorganic oxide is preferably in the form of particles. The conductive inorganic oxide preferably has the average particle diameter that is in a range of 10 to 30 nm. The average particle diameter is measured by a laser diffraction scattering method.

The conductive material is prepared by dispersing the conductive inorganic oxide and binder resin to an appropriate solvent when the first electrode 4 containing the conductive inorganic oxide is formed. As an example of the binder resin, modified acrylic resin may be used. Examples of the modified acrylic resin include urethane modified acrylic resin, polyether modified acrylic resin, polycarbonate modified acrylic resin, polyether modified acrylic resin, and fluorine modified acrylic resin. As an example of the solvent, alcohol may be used. The conductive material is heated after being applied on the surface of the light scattering layer 3, in order to evaporate the solvent and the binder resin, and accordingly, the first electrode 4 is formed. Examples of the coating method include a roll coating method, a spin coating method, and a dip coating method. The heating temperature for the conductive material is preferably in a range of 80 degrees to 200 degrees.

The metallic nano-material may include at least one component of metallic nanowires and metallic nanoparticles when the first electrode 4 containing the metallic nano-material is formed. In particular, the metallic nano-material preferably contains the metallic nanowires or preferably contains the metallic nanowires and the metallic nanoparticles.

The metallic nanowires each is a metallic fiber having a nanosized (1 to 1000 nm) diameter. Examples of the metal constituting the metallic nanowires include Ag, Au, Cu, Co, Al, and Pt. There is no limitation in particular, regarding a method of manufacturing the metallic nanowires. For example, as the method of manufacturing the metallic nanowires, a known method such as a liquid phase method or a gas phase method may be taken. Concrete examples of a method of manufacturing Ag nanowires include methods disclosed in a document (Adv. Mater. 2002, 14, p. 833 to p. 837), a document (Chem. Master. 2002, 14, p. 4736 to p. 4745), and a document (JP2009-505358 A).

The metallic nanowires preferably have the average diameter that is in a range of 10 to 100 nm. In this case, especially transparency of the first electrode 4 is improved with an increase in electrical conductivity of the first electrode 4. The metallic nanowires more preferably have the average diameter that is in a range of 20 to 100 nm, and the best average diameter is in a range of 40 to 100 nm. In addition, the metallic nanowires preferably have the average length that is in a range of 1 to 100 μm. In this case, especially transparency of the first electrode 4 is improved with an increase in electrical conductivity of the first electrode 4. The average length of the metallic nanowires is more preferably in a range of 1 to 50 μm, and the best average length is in a range of 3 to 50 μm. The average diameter of the metallic nanowires is obtained by subjecting diameters of the metallic nanowires to the arithmetic mean. The average length of the metallic nanowires is obtained by subjecting lengths of the metallic nanowires to the arithmetic mean. The diameters and the lengths of the meal nanowires are derived by analyzing an electron microscope image of the metallic nanowires.

Regarding the first electrode 4, a ratio of the metallic nanowires is preferably in a range of 0.01 to 90 mass %, more preferably in a range of 0.1 to 30 mass %, and the best is a range of 0.5 to 10 mass %.

The metallic nanoparticles are the metallic particles having nanosized (1 to 1000 nm) diameter. Examples of the material for the metallic nanoparticles include Ag, Au, Cu, Ni, Co, Hg, Zn, Fe, Al, and Pt.

The metallic nanoparticles preferably have an average particle diameter that is in a range of 1 to 200 nm, more preferably in a range of 5 to 150 nm, and the best is a range of 10 to 100 nm. The average particle diameter of the metallic nanoparticles is obtained by measuring, when a sufficient number of particles are converted into true circles, diameters of the true circles, and subjecting the measured diameters to the arithmetic mean. The diameters of the true circles are derived by analyzing an electron microscope image of the particles.

Regarding the first electrode 4, a ratio of the metallic nanoparticles is preferably in a range of 0.1 to 10 mass % with respect to the metallic nanowires, and more preferably in a range of 1 to 5 mass %.

When metallic nano-material is used, the first electrode 4 is formed of conductive material containing the metallic nano-material and a resin component, for example. In this case, the first electrode 4 may be formed by a wet film forming method.

Examples of the resin components include thermoplastics resin and reactive curable resin. Examples of the thermoplastics resin include cellulose resin, silicone resin, fluoric resin, acrylic resin, polyethylene resin, polypropylene resin, polyethylene terephthalate resin, and polymethylmethacrylate resin. At least one resin of thermosetting resin and ionizing radiation curable type resin may be preferably used from as reactive curable resin. Example of the thermosetting resin includes phenolic resin, urea resin, diallyl phthalate resin, melamine resin, unsaturated polyester resin, polyurethane resin, epoxy resin, aminoalkyd resin, silicone resin, and polysiloxane resin. The composition may contain cross-linker, polymerization initiator, curing agent, curing accelerator, and solvent with thermosetting resin as needed. Resin having acrylate type functional group may be preferably used as the ionizing radiation curable type resin. Examples of the resin having the acrylate type functional group include oligomer and prepolymer such as (meth)acrylate of a multifunctional compound with a relatively-low molecular weight. Examples of the multifunctional compound include polyester resin, polyether resin, acrylic resin, epoxy resin, urethane resin, alkyd resin, spiroacetal resin, polybutadiene resin, polythiol polyene resin, and polyhydric alcohol. The component having the ionizing radiation curable type resin further preferably contains a reactive diluent. Examples of the reactive diluent include: a monofunctional sensuality monomer, such as ethyl (meth) acrylate, ethyl hexyl (meth) acrylate, styrene, methyl styrene, and N-vinyl pyrrolidone; multifunctionalmonomer, such as trimethylol propane tri(meth) acrylate, hexanediol (meth) acrylate, tripropylene glycol di(meth) acrylate, diethylene glycol di(meth) acrylate, pentaerythritol tri(meth) acrylate, dipentaerythritol hexa(meth) acrylate, 1,6-hexanediol di(meth) acrylate, and neopentylglycol di(meth) acrylate.

When the ionizing radiation curable type resin is a photocurable resin such as ultraviolet curable resin, the conductive material further preferably contains photopolymerization initiator. Examples of the photopolymerization initiator include acetophenone, benzophenone, a-amyloxime ester, and thioxanthone. The composition containing the photocurable resin may include a photo sensitizer along with or instead of the photopolymerization initiator. Examples of the photo sensitizer include n-butylamine, triethylamine, tri-n-butyl phosphine, and thioxanthone.

The conductive material containing a metallic nano-material may contain a solvent as needed. Examples of the solvent include an organic solvent, water, and both of them. Examples of the organic solvent include: alcohols such as methanol, ethanol, and isopropyl alcohol (IPA); ketones such as methyl ethyl ketone, methyl isobutyl ketone, and cyclohexanone; esters such as ethyl acetate, and butyl acetate; halogenated hydrocarbons; aromatic hydrocarbons such as toluene, and xylene; and mixtures including those.

The quantity of the solvent in the conductive material is appropriately adjusted in order to dissolve and disperse a solid content uniformly in the conductive material. The concentration of the solid content in the conductive material is preferably in a range of 0.1 to 50 mass % and more preferably in a range of 0.5 to 30 mass %.

The conductive material is coated and formed into film, and accordingly, the first electrode 4 is formed. An appropriate coating method such as a roll coating method, a spin coating method, or a dip coating method may be taken. The method of forming the film with the conductive material is appropriately selected in accordance with the type of resin component or the like in the conductive material. For example, when the conductive material contains thermosetting resin, the first electrode 4 having a metallic nano-material is formed by the conductive material being cured by heating. In addition, when the conductive material contains ionizing radiation curable type resin, the first electrode 4 containing a metallic nano-material is formed by the conductive material being exposed to ionizing radiation, such as ultraviolet rays, to be cured.

When the first electrode 4 containing a conductive polymer is formed, a monomer constituting the conductive polymer may be selected from pyrrole, thiophene, aniline, acetylene, ethylene vinylidene, fluorene, vinyl carbazole, vinyl phenol, benzene, pyridine, and these derivatives. The conductive polymer may be constituted by only one or more than two kinds of monomer. For example, the conductive polymer may contain at least one of polypinole and poly (3,4-ethylenedioxythiofen).

When the first electrode 4 containing the conductive polymer is formed, conductive material containing the conductive polymer and a solvent may be used. Examples of the solvent include an organic solvent, water, and both of them. Examples of the organic solvent include: alcohols such as methanol, ethanol, and isopropyl alcohol (IPA); ketones such as methyl ethyl ketone, methyl isobutyl ketone, and cyclohexanone; esters such as ethyl acetate, and butyl acetate; halogenated hydrocarbons; aromatic hydrocarbons such as toluene, and xylene; and mixtures including those. The quantity of the solvent in the composition is appropriately adjusted in order to dissolve and disperse a solid content uniformly in the composition. The concentration of the solid content in the composition is preferably in a range of 0.1 to 50 mass % and more preferably in a range of 0.5 to 30 mass %. The first electrode 4 is formed by coating the conductive material and forming the conductive material into a film. An appropriate method of coating the conductive material such as a roll coating method, a spin coating method, or a dip coating method may be taken.

When the first electrode 4 is formed by applying the conductive material and formed into a film as mentioned above, part of the first electrode 4 is filled into the recesses 7 as the conductive material is easily filled into the recesses 7 in the surface of the light scattering layer 3. Namely, the first electrode 4 adheres to the light scattering layer 3 because projections following the recesses 7 in the light scattering layer 3 are formed on a surface of the first electrode 4, which is in contact with the light scattering layer 3. For this reason, an uneven interface is easily formed between the light scattering layer 3 and the first electrode 4. Therefore, as mentioned above, when light from the organic light-emitting layer 5 is emitted to the outside through the substrate 2, the light is easily scattered on the interface between the light scattering layer 3 and the first electrode 4. This can realize improving light extraction efficiency from the organic electroluminescent element 1.

The first electrode 4 preferably has a refractive index larger or smaller than that of the light scattering layer 3. In this case, the light is more easily scattered on the interface between the light scattering layer 3 and the first electrode 4, and accordingly, the light extraction efficiency is more improved. In particular, an absolute value of a difference between the refractive indexes of the first electrode 4 and light scattering layer 3 is preferably in a range of 0.1 to 0.3.

For example, when the light scattering layer 3 is formed of resin component containing a filing material, and the first electrode 4 contains a conductive inorganic oxide, it is easy to adjust the refractive index of the light scattering layer 3 by regulating a kind of resin in the resin composition, a kind or a ratio of the filing material, or the like. Therefore, it is easy to obtain a lower refractive index of the light scattering layer 3 than that of the first electrode 4 and to adjust the difference between the refractive indexes to a desired value.

The thickness of the first electrode 4 is not limited in particular. However, a thickness of the thickest part of first electrode 4 is larger than a depth of the recesses 7 because part of the first electrode 4 is filled into the recesses 7. The thickness of the thickest part of the first electrode 4 is preferably in a range of 0.5 to 3.0 μm. In addition, a thickness of the thinnest part of the first electrode 4 is preferably in a range of 0.3 to 1.2 μm.

As shown in FIG. 1D, the first electrode 4 preferably has an uneven surface on an opposite side of the first electrode 4 from the light scattering layer 3. In this case, an uneven interface is also formed between the first electrode 4 and the organic light-emitting layer 5. Therefore, when light from the organic light-emitting layer 5 is emitted to the outside through the substrate 2, the light is easily scattered on the interface between the first electrode 4 and the organic light-emitting layer 5. This can realize improving light extraction efficiency from the organic electroluminescent element 1.

The larger the difference in height of the uneven surface on an opposite side of the first electrode 4 from the light scattering layer 3 is, the easier the light is scattered on the interface between the first electrode 4 and the organic light-emitting layer 5. However, if the difference in height is too large, there is a possibility generating a short circuit in the organic electroluminescent element 1. For this reason, the difference in height of the uneven surface is preferably in a range of 200 to 400 nm. In addition, the difference in height of the uneven surface is defined as a difference in height between a projection and a recess adjacent to the projection on the opposite side of the first electrode 4 from the light scattering layer 3.

When the first electrode 4 is formed, the uneven surface of the opposite side of the first electrode 4 from the light scattering layer 3 is formed by an appropriate adjustment of the viscosity of the conductive material. When the conductive material has a high viscosity to some extent, a surface shape of the coating film of the conductive material easily follows shapes of the recesses 7 in the light scattering layer 3 upon applying the conductive material on the light scattering layer 3. Therefore, the coating film surface can easily become an uneven surface. As a result, the uneven surface is formed on an opposite side of the first electrode 4, made by forming the conductive material into a film, from the light scattering layer 3. In this case, the viscosity of the conductive material is appropriately set according to the degree of the uneven surface formed on an opposite side of the first electrode 4 from the light scattering layer 3, shapes of the recesses 7 in the light scattering layer 3, a thickness of the first electrode 4 and the like.

After the first electrode 4 is formed, as shown in FIG. 1E, the organic light-emitting layer 5, and the second electrode 6 are formed in this order.

The organic light-emitting layer 5 includes a light-emitting layer. The organic light-emitting layer 5 may further include more than one kind from the hole injection layer, the hole transport layer, the electron transport layer, and the electron injection layer if necessary. The organic light-emitting layer 5 has the laminated structure including, for example, the hole injection layer, the hole transport layer, the light-emitting layer, the electron transport layer, and the electron injection layer stacked in this order.

Examples of the material for forming the hole injection layer include: a conductive polymer such as PEDOT/PSS or polyaniline; a conductive polymer that is doped with any acceptor or the like; and a material having conductivity and a light transmissive property such as carbon nanotubes, CuPc (copper phthalocyanine), MTDATA[4,4′,4″-Tris(3-methyl-phenylphenylamino)tri-phenylamine], TiOPC (titanyl phthalocyanine), or amorphous carbon. The hole injection layer can be obtained by an appropriate method such as a coating method or a vapor deposition.

The material constituting the hole transport layer (hole transporting material) is appropriately selected from a group of compounds having a hole transporting property. However, it is preferable that the hole transporting material is a compound that has a property of donating electrons and is stable even when undergoing radical cationization due to electron donation. Instances of the hole transporting material include: triarylamine-based compounds, amine compounds containing a carbazole group, amine compounds containing fluorene derivatives, and starburst amines (m-MTDATA), representative instances of which include polyaniline, 4,4′-bis[N-(naphthyl)-N-phenyl-amino]biphenyl (α-NPD), N,N′-bis(3-methylphenyl)-(1,1′-biphenyl)-4,4′-diamine (TPD), 2-TNATA, 4,4′-4″-tris(N-(3-methylphenyl)N-phenylamino)triphenylamine (MTDATA), 4,4′-N,N′-dicarbazole biphenyl (CBP), spiro-NPD, spiro-TPD, spiro-TAD, and TNB; and 1-TMATA, 2-TNATA, p-PMTDATA, TFATA or the like as a TDATA-based material, but the hole transporting material is not limited to these, and any hole transporting material that is generally known may be used. The hole transport layer can be formed by an appropriate method such as a coating method or a vapor deposition.

The light-emitting layer is a layer of generating light emission in the organic light-emitting layer. The light-emitting layer may be formed of the known materials for the organic electroluminescent element. Concrete examples of material for forming the light-emitting layer include: anthracene, naphthalene, pyrene, tetracene, coronene, perylene, phthaloperylene, naphthaloperylene, diphenylbutadiene, tetraphenylbutadiene, coumalin, oxadiazole, bisbenzoxazoline, bisstyryl, cyclopentadiene, a quinoline-metal complex, a tris(8-hydroxyquinolinate)aluminum complex, a tris(4-methyl-8-quinolinate)aluminum complex, a tris(5-phenyl-8-quinolinate)aluminum complex, an aminoquinoline-metal complex, a benzoquinoline-metal complex, a tri-(p-terphenyl-4-yl)amine, 1-aryl-2,5-di(2-thienyl)pyrrole derivative, pyrane, quinacridone, rubrene, a distyrylbenzene derivative, a distyrylarylene derivative, a distyrylamine derivative, and various phosphor pigments. More than two kinds of material may be combined to be used. Moreover, not only material generating fluorescence emission but also material generating spin multiplet luminescence such as phosphorescence emission or compound having a part of generating spin multiplet luminescence in a molecule may be used. A light-emitting layer may be formed by a dry process such as a vapor deposition or a transfer method, or by a wet process such as a coating method.

It is preferable that the material for forming the electron transport layer (electron transporting material) is a compound that has the ability to transport electrons, can accept electrons injected from the second electrode 6, and produces excellent electron injection effects on the light-emitting layer, and moreover, prevents the movement of holes to the electron transport layer and is excellent in terms of thin film formability. Instances of the electron transporting material include Alq3, oxadiazole derivatives, starburst oxadiazole, triazole derivatives, phenylquinoxaline derivatives, and silole derivatives. Specific instances of the electron transporting material include fluorene, bathophenanthroline, bathocuproine, anthraquinodimethane, diphenoquinone, oxazole, oxadiazole, triazole, imidazole, anthraquinodimethane, 4,4′-N,N′-dicarbazole biphenyl (CBP), etc., compounds thereof, metal-complex compounds, and nitrogen-containing five-membered ring derivatives. Specifically, instances of the metal-complex compounds include tris(8-hydroxyquinolinato)aluminum, tri(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)(o-cresolate)gallium, bis(2-methyl-8-quinolinato)(1-naphtholate)aluminum, and bis(2-methy-8-quinolinato)-4-phenylphenolato, but are not limited thereto. Preferable instances of the nitrogen-containing five-membered ring derivatives include oxazole, thiazole, oxadiazole, thiadiazole, and triazole derivatives, and specific instances thereof include 2,5-bis(1-phenyl)-1,3,4-oxazole, 2,5-bis(1-phenyl)-1,3,4-thiazole, 2,5-bis(1-phenyl)-1,3,4-oxadiazole, 2-(4′-tert-butylphenyl)-5-(4″-biphenyl)1,3,4-oxadiazole, 2,5-bis(1-naphthyl)-1,3,4-oxadiazole, 1,4-bis[2-(5-phenylthiadiazolyl)]benzene, 2,5-bis(1-naphthyl)-1,3,4-triazole, and 3-(4-biphenylyl)-4-phenyl-5-(4-t-butylphenyl)-1,2,4-triazole, but are not limited thereto. Instances of the electron transporting material further include the polymer material used for the organic electroluminescent element. Instances of this polymer material include polyparaphenylene and derivatives thereof, and fluorene and derivatives thereof. The electron transport layer may be formed by an appropriate method such as a coating method or a vapor deposition. The thickness of the electron transport layer is not limited in particular. However, for instance, the thickness is in a range of 10 to 300 nm.

Instances of the material for forming the electron injection layer include an alkali metal, alkali metal halides, alkali metal oxides, alkali metal carbonates, an alkaline earth metal, and an alloy including these metals. Specific instances thereof include sodium, a sodium-potassium alloy, lithium, lithium fluoride, Li₂O, Li₂CO₃, magnesium, MgO, a magnesium-indium mixture, an aluminum-lithium alloy, and an Al/LiF mixture. The electron injection layer may be formed with an organic layer that is doped with an alkali metal such as lithium, sodium, cesium, or calcium, an alkaline earth metal, or the like. The electron injection layer can be formed by an appropriate method such as a vapor deposition.

The second electrode 6 functions as a cathode in the present embodiment. The cathode of the organic electroluminescent element 1 is the electrode for injecting electrons into the light-emitting layer. It is preferable that the second electrode 6 is formed of a material such as a metal, alloy, or electrically conductive compound that has a small work function, or a mixture thereof. Particularly, it is preferable that the second electrode 6 is formed of a material having a work function of 5 eV or less. In other words, it is preferable that the work function of the second electrode 6 is less than or equal to 5 eV. Examples of a material for forming such a second electrode 6 include Al, Ag, and MgAg. The second electrode 6 may be formed of an Al/Al₂O₃ mixture or the like. The second electrode 6 can be formed by an appropriate method such as a vacuum vapor deposition or a sputtering method, using these materials. It is preferable that the light transmittance of the second electrode 6 is 10% or less. The thickness of the second electrode 6 is appropriately set such that properties such as the light transmittance and sheet resistance of the second electrode 6 are approximately desired values. Although a preferable thickness of the second electrode 6 changes depending on the material constituting the second electrode 6, the thickness of the second electrode 6 may be set to be less than or equal to 500 nm, and preferably set to be in a range of 20 nm to 200 nm.

In the present embodiment, mesh-shaped metal wires may be provided between the first electrode 4 and the organic light-emitting layer 5. In this case, decreasing electrical resistance of the organic electroluminescent element 1 can be realized by the metal wires.

In the present embodiment, the first electrode 4 functions as an anode and the second electrode 6 functions as a cathode. However, on the contrary, the second electrode 6 may function as an anode and the first electrode 4 may function as a cathode. In this case, the organic light-emitting layer 5 has a laminated structure in which the hole injection layer, the hole transport layer, the light-emitting layer, the electron transport layer, and the electron injection layer are laminated in reverse order with respect to the first electrode 4 and the second electrode 6.

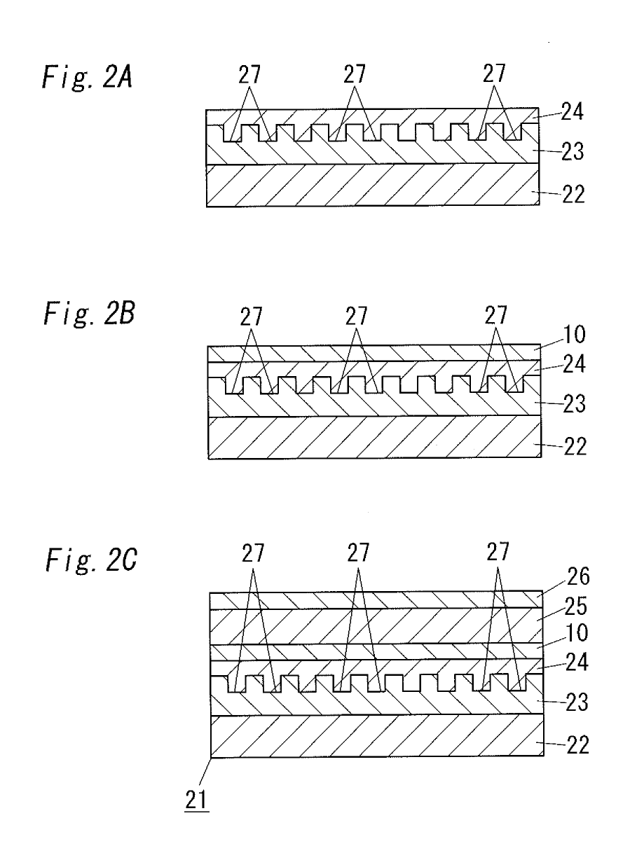

FIG. 2C schematically shows a structure of an organic electroluminescent element 21 (organic light-emitting diode) according to a second embodiment. The organic electroluminescent element 21 includes a light transmissive substrate 22, a first electrode 24, an organic light-emitting layer 25, and a second electrode 26 which are stacked in this order. Furthermore, a light scattering layer 23 is provided between the substrate 22 and the first electrode 24. The light scattering layer 23 is in contact with the first electrode 24. Moreover a conductive layer 10 is provided between the first electrode 24 and the organic light-emitting layer 25. The conductive layer 10 is in contact with the first electrode 24. A sheet resistance value of the conductive layer 10 is equal to or less than that of the first electrode 24. Namely, in the present embodiment the substrate 22, the light scattering layer 23, the first electrode 24, the conductive layer 10, the organic light-emitting layer 25, and the second electrode 26 are stacked in this order. The substrate 22 and the light scattering layer 23 may not be necessary in contact with each other directly, and the first electrode 24 and the conductive layer 10 may not be necessary in contact with each other directly, and the conductive layer 10 and the organic light-emitting layer 25 may not be necessary in contact with each other directly, and the organic light-emitting layer 25 and the second electrode 26 may not be necessary in contact with each other directly. However, the light scattering layer 23 and the first electrode 24 should be contact with each other directly.

The first electrode 24 is preferably formed of a coating type conductive film. Moreover, the light scattering layer 23 is preferably formed of an organic material. A surface of the light scattering layer 23 being in contact with the first electrode 4 is provided with the recesses 27.

Furthermore, in the organic electroluminescent element 21 according to the present embodiment, as well as the first embodiment, an uneven interface is formed between the light scattering layer 23 and the first electrode 24. Therefore, when light from the organic light-emitting layer 25 is emitted to the outside through the substrate 22, the light is easily scattered on the interface between the light scattering layer 23 and the first electrode 24. This can realize improving light extraction efficiency from the organic electroluminescent element 21.

As mentioned above, in the present embodiment as well as the first embodiment, it is possible to improve light extraction efficiency from the organic electroluminescent element 21 by an easy configuration such as having the light scattering layer 23 between the substrate 22 and the first electrode 24.

Furthermore, in the present embodiment, a conductive layer 10 is provided between the first electrode 24 and the organic light-emitting layer 25 and a sheet resistance value of the conductive layer 10 is equal to or less than that of the first electrode 24. Therefore, the conductive layer 10 can prevent uniformity of electric current density when current flows between the first electrode 24 and the organic light-emitting layer 25. The reason is below.

Because part of the first electrode 24 is filled into the recesses 27 in the surface of the light scattering layer 23, the thickness of the first electrode 24 is hard to be kept constant. Therefore, uniformity of an electric resistance in the first electrode 24 easily occurs. As a result, when current flows between the first electrode 24 and the organic light-emitting layer 25, uniformity of electric current density easily occurs. However, as in the present embodiment, when the conductive layer 10 having lower sheet resistance is provided between the first electrode 24 and the organic light-emitting layer 25, the conductive layer 10 uniforms electric current density. Therefore, the uniformity of the electric resistance hardly occurs. As a result, it prevents uniformity of emission intensity of the organic electroluminescent element 21.

In addition, even if the first electrode 24 contains a substance such as an organic substance having an influence on the characteristics of the organic light-emitting layer 25, interposing of the conductive layer 10 between the first electrode 24 and the organic light-emitting layer 25 prevents the substance from transferring from the first electrode 24 to the organic light-emitting layer 25. Therefore, the performance deterioration of the organic electroluminescent element 21 is suppressed, and accordingly, it is possible to obtain the organic electroluminescent element 21 having higher light emitting efficiency and a longer lifetime. Moreover, it is possible to expand a selection range of a material for manufacturing the first electrode 24. In particular, in the present embodiment, since the first electrode 24 is formed by a coating method, the first electrode 24 may include, as components or impurities, an organic matter such as resin. When such an organic matter moves to the organic light-emitting layer 25, the performance deterioration of the organic electroluminescent element 21 may occur. However, the conductive layer 10 can suppress such a situation.

In addition, even if a gas is released from the light scattering layer 23 formed of an organic material, the conductive layer 10 blocks the gas from reaching the organic light-emitting layer 25. Therefore, the organic light-emitting layer 25 is hard to be suffered from damage due to the gas and is hard to have defects such as dark spots. In this case, in selecting the organic material for forming the light scattering layer 23, there is no need to consider the release of the gas from the light scattering layer 23, and accordingly, a selection range of the organic material is expanded. Therefore, it can be easier to select the organic material having characteristics such as a desired refractive index and a formability without considering the release of the gas. As a result, the organic electroluminescent element 21 having a high emission luminance, a low driving voltage, and high reliability can be easily obtained.

The details of the configuration of the organic electroluminescent element 21 according to the present embodiment and the method of preparing the same are described below.

The configurations of the substrate 22 and the light scattering layer 23 in the present embodiment are the same as those of the substrate 2 and the light scattering layer 3 in the first embodiment, respectively. In addition, the method of forming the light scattering layer 23 on the substrate 22 is the same as that of forming the light scattering layer 3 on the substrate 2 in the first embodiment.

The first electrode 24 is preferably formed of a coating type conductive film. Namely, as with the first electrode 4 in the first embodiment, the first electrode 24 preferably includes a conductive film which is formed by coating conductive material having fluidity and forming the conductive material into a film.

In the present embodiment, as shown in FIG. 2A, the first electrode 24 may be formed by the same method as the method of forming the first electrode 4 in the first embodiment, using the same conductive material in the first embodiment.

However, in the present embodiment, the surface on an opposite side of the first electrode 24 from the light scattering layer 23 is formed flatly. To form such a first electrode 24, preferably the viscosity of the conductive material is adjusted appropriately. When the conductive material has a low viscosity to some extent, a surface shape of the coating film of the conductive material is difficult to follow shapes of the recesses 27 in the light scattering layer 23 upon applying the conductive material on the light scattering layer 23. For this reason, the coating film surface can easily become flatly. Therefore, the surface on an opposite side of the first electrode 24, made by forming the conductive material into a film, from the light scattering layer 23 is formed flatly. In this case, the viscosity of the conductive material is set appropriately according to the shapes of the recesses 27 in the light scattering layer 23, the thickness of the first electrode 24 and the like.

After the first electrode 24 being formed, as shown in FIG. 2B, the conductive layer 10 is formed on the first electrode 24. The conductive layer 10 is preferably formed on the first electrode 24 by a vapor deposition such as a vacuum vapor deposition or a sputtering method. In this case, because a dense conductive layer 10 is formed, a sheet resistance value of the conductive layer 10 is easily reduced. Therefore, the conductive layer 10 having the sheet resistance value, which is equal to or less than that of the first electrode 24, is easily formed

Concrete examples of material for forming the conductive layer 10 include metal oxides such as ITO (indium-tin oxide), SnO2, ZnO, IZO (indium-zinc oxide), and AZO (aluminum addition zinc oxide). The light transmittance of the conductive layer 10 is preferably equal to or more than 70% and more preferably equal to or more than 90%.

When formed of an organic material, normally the light scattering layer 23 is easily damaged. However, when the conductive layer 10 is formed on the first electrode 24 by a vapor deposition, the first electrode 24 protects the light scattering layer 23. Therefore, even though the vapor deposition is applied, the light scattering layer 23 is hard to be damaged. In particular, a sputtering method normally easily damages a base. However, even if the conductive layer 10 is formed by such a sputtering method, the light scattering layer 23 is hard to be damaged.

The first electrode 24 and the conductive layer 10 preferably contain the common material. In other word, the first electrode 24 and the conductive layer 10 preferably contain the same kinds of materials. In this case, because affinity between the first electrode 24 and the conductive layer 10 is high, it improves adhesion therebetween and minimizes peeling of the conductive layer 10 from the first electrode 24. Therefore, the reliability of the organic electroluminescent element 21 improves and the yield of the organic electroluminescent element 21 in manufacturing improves.

When the first electrode 24 contains a conductive inorganic oxide for example, the conductive layer 10 is preferably formed of a conductive inorganic oxide which is the same kind as the conductive inorganic oxide of the first electrode 24. Namely, when the first electrode 24 contains ITO for example, the conductive layer 10 is preferably also formed of ITO. In this case, the adhesion between the first electrode 24 and the conductive layer 10 improves. In addition, even when the first electrode 24 and the conductive layer 10 include the same kinds of the conductive inorganic oxides, the conductive layer 10 is densely made by a vapor deposition more easily, compared with the first electrode 24 made of a coating type conductive film. Therefore, the sheet resistance value of the conductive layer 10 is easily adjusted to be equal to or less than that of the first electrode 24.

The sheet resistance value of the conductive layer 10 is preferably in a range of 5 to 30% in that of the first electrode 24. In this case, in particular the uniformity of emission intensity of the organic electroluminescent element 21 is suppressed.

In addition, the thickness of the conductive layer 10 is preferably equal to or less than 500 nm and more preferably in a range of 20 to 200 nm.

The conductive layer 10 is preferably heated after being formed. In this case, the sheet resistance value of the conductive layer 10 can be decreased. Therefore, the sheet resistance value of the conductive layer 10 is easily adjusted to be equal to or less than that of the first electrode 24. When being heated, the conductive layer 10 is preferably heated at the temperature of 200 to 300 degrees for 30 to 180 minutes.

When being heated, the conductive layer 10 is preferably heated by an induction heating method. In this case, when the conductive layer 10 is heated, the light scattering layer 23 made of an organic material is hard to be heated. Therefore the light scattering layer 23 is hard to be damaged due to heat.

As shown in FIG. 2C, the organic light-emitting layer 25 is formed on the conductive layer 10 and the second electrode 26 is formed on the organic light-emitting layer 25, and accordingly, the organic electroluminescent element 21 can be obtained. The configurations of the organic light-emitting layer 25 and the second electrode 26 in the present embodiment are the same as those of the organic light-emitting layer 5 and the second electrode 6 in the first embodiment, respectively. In addition, the methods of preparing the organic light-emitting layer 25 and the second electrode 26 are the same as those of preparing the organic light-emitting layer 5 and the second electrode 6 in the first embodiment, respectively.

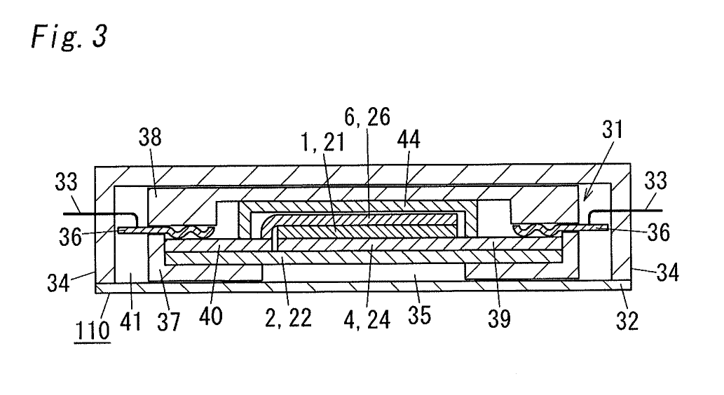

The organic electroluminescent elements 1, 21 each are suitable as a light source of a lighting fixture. An example of a lighting fixture including the organic electroluminescent element 1, or 21 is shown in FIG. 3. The lighting fixture 11 includes a unit 31 including the organic electroluminescent element 1, or 21, a housing 34, a front panel 32, wires 33, and power supply terminals 36.

The unit 31 includes the organic electroluminescent element 1, or 21, a front case 37, and a back case 38. The organic electroluminescent element 1, or 21 includes a first wiring 39, a second wiring 40, and a sealing substrate 44. The first wiring 39 and the second wiring 40 are provided on the substrate 2, or 22. The first wiring 39 is connected to the first electrode 4, or 24. The second wiring 40 is connected to the second electrode 6, or 26. The sealing substrate 44 is fixed on the substrate 2, or 22 and covers the laminate including the first electrode 4, or 24, the organic light-emitting layer, the second electrode 6, or 26, and the light scattering layer. The organic electroluminescent element 1, or 21 is held in a space between the front case 37 and the back case 38. The front case 37 is provided with an opening 35 faced to the substrate 2, or 22 of the organic electroluminescent element 1, or 21.

The housing 34 is configured to hold the unit 31. The housing 34 has a recess 41, and the unit 31 is hold in the recess 41. An opening of the recess 41 is blocked by the light transmitting front panel 32.

In addition, two wires 33 are provided from outside to inside of the housing 34. These wires 33 are connected to an external power source. Moreover, two power supply terminals 36 are fixed between the front case 37 and the back case 38. Two wires 33 are connected to respectively two power supply terminals 36, and these two power supply terminals 36 are connected to respectively the first wiring 39 and the second wiring 40. Therefore, electric power can be supplied from the external power source through the wires 33 and the power supply terminals 36 to the organic electroluminescent element 1, or 21.

In the lighting fixture 11 configured as above, when the electric power is supplied from the external power source through the wires 33 and the power supply terminals 36 to the organic electroluminescent element 1, or 21, the organic electroluminescent element 1, or 21 emits light. The light is emitted to the outside thorough the substrate 2, or 22, the opening 35, and the front panel 32.

### EXAMPLE

Example 1

A glass substrate was prepared as a substrate. A coating film in an uncured state was formed by coating and drying ultraviolet curable acrylic resin on the substrate. The coating film was embossed by pressing quartz glass mold having a plurality of projections with width of 1.2 μm and a projection size of 1.2 μm. While pressing the mold to the coating film, the coating film was cured by an irradiation of ultraviolet rays through the mold, and then the mold was separated. As a result, a light scattering layer with the refractive index of 1.5 was formed. On the light scattering layer, a plurality of recesses, each of which has a width of 1.2 μm and a depth of 1.2 μm, respectively corresponding to the plurality projections of the mold were formed.

A conductive material containing ITO particles (the average particle diameter 50 nm), modified acrylic resin and alcohol was prepared, and the ratio of the ITO particles was adjusted to 10 mass %. A first electrode was formed by coating the conductive material on the light scattering layer and drying it. The refractive index of the first electrode was 1.9, the sheet residence value was 150 Ω/sq., the maximum of the thickness was 1.4 μm, and the minimum of the thickness was 0.1 μm.

In addition, a surface on an opposite side of the first electrode from the light scattering layer was formed into an uneven surface with a height difference in a range of 200 to 400 nm.

Moreover, following five things were formed by a vacuum vapor deposition. First of all, a hole injection layer with the thickness of 20 nm made of CuPc was formed on the first electrode by a vacuum vapor deposition. Secondly, a hole transport layer with the thickness of 100 nm made of TPD was formed by a vacuum vapor deposition. Thirdly, a light-emitting and electron-transport layer with the thickness of 50 nm made of Alq3 was formed by a vacuum vapor deposition. Fourthly, an electron injection layer with the thickness of 2 nm made of Li was formed by a vacuum vapor deposition. Lastly, a second electrode with the thickness of 100 nm made of Al was formed by a vacuum vapor deposition. As a result, an organic electroluminescent element was obtained.

### Example 2

A light scattering layer was formed on a substrate by the same method as the example 1.

A conductive material containing ITO particles (the average particle diameter 50 nm), modified acrylic resin and alcohol was prepared, and the ratio of the ITO particles was adjusted to 10 mass %. A first electrode was formed by coating the conductive material on the light scattering layer and drying it. The refractive index of the first electrode was 1.9, the sheet residence value was 300 Ω/sq., the maximum of the thickness was 1.6 μm, and the minimum of the thickness was 0.1 μm. In addition, a surface on an opposite side of the first electrode from the light scattering layer was formed flatly.

Next, a conductive layer with the thickness of 200 nm made of ITO was formed on the first electrode by a spattering method. The conductive layer was heated by an induction heating method at temperature of 250 degrees for 3 hours. The sheet residence value of the conductive layer was 12 Ω/sq.

Moreover, a hole injection layer, a hole transport layer, a light-emitting layer, an electron transport layer, an electron injection layer, and a second electrode were formed on the conductive layer in this order by the same method as the example 1. As a result, an organic electroluminescent element was obtained.

In the present example, the first electrode was formed of the conductive layer containing ITO particles. However, the material for the first electrode is not limited to it. For example, the first electrode may be formed by coating dispersed solution, such as nanoAg ink or carbon nanotube, to form a film. In this way, when the first electrode is formed of nanoAg ink or carbon nanotube, the electric resistance value of the first electrode can be easily decreased, compared with a case where the first electrode is formed of ITO. Therefore, reduction in cost due to thinning of the first electrode is achieved.

### Comparative Example 1

A glass substrate was prepared as a substrate. On the substrate, a first electrode with the thickness of 200 nm made of ITO was formed by a spattering method. In addition, a hole injection layer, a hole transport layer, a light-emitting layer, an electron transport layer, an electron injection layer, and a second electrode were formed on the first electrode in this order by the same method as the example 1. As a result, an organic electroluminescent element was obtained.

### EVALUATION

The organic electroluminescent elements obtained by the example 1 and the comparative example 1 were supplied with constant current of 4 mA/cm². Emission luminances of the organic electroluminescent elements were measured in this state with a colorimeter (CS-1000, KONICA MINOLTA, INC.). The result was 1300 cd/m² in the example 1, and 240 cd/m² in the comparative example 1. That is, the emission luminance of the example 1 was higher than that of the comparative example 1. In addition, a voltage value per emission luminance of the example 1 was reduced to 80% with respect to that of the comparative example 1.

Moreover, the chromaticity of light emitted from the organic electroluminescent element in the front direction, and the chromaticity of light emitted in a direction inclined by 80° from the front direction were measured with the colorimeter. In this case, the degree of a change in the chromaticity of light accompanying a change in a light emitting direction was evaluated, using Δu′v′, which denotes a change of a chromaticity coordinate (a u′v′ coordinate defined by CIE 1976 UCS chromaticity diagram). Here, Δu′v′ was defined as below.

Δu′v′={square root over ((u′(80)−u′(0))²+(v′(80)−v′(0))²)} (Formula 1)

Note that, u′(80) is an u′ value of the light emitted from the element in a direction inclined by 80° from the front direction, u′(0) is an u′ value of the light emitted from the element in the front direction, v′(80) is a v′ value of the light emitted from the element in the direction inclined by 80° from the front direction, and v′(0) is a v′ value of the light emitted from the element in the front direction.

In the result, Δu′v′ was 0.01 in the example 1 and was 0.02 in the comparative example 1. That is, the example 1 had less change in the emission color accompanying the change in the light emitting direction, compared with the comparative example 1. As a result, regarding the example 1, it was confirmed that the change in the emission color accompanying the change in the light emitting direction was suppressed by the scattering function of the light scattering layer.

In the same way, the emission luminance and Δu′v′ of the organic electroluminescent element obtained in the example 2 were measured. As a result, a voltage value per emission luminance of the example 2 was reduced to 70% with respect to that of the comparative example 1. In addition, Δu′v′ in the example 2 was the same as that in the example 1.

In addition, the organic electroluminescent element obtained in the example 2 was arranged in a thermostat at temperature of 85 degrees and relative humidity of 85% RH for 500 hours. After that, the organic electroluminescent element was taken out from the thermostat, and was observed while being made to emit light. In this case, any dark spots were not founded. According to the result, it is considered that regarding the organic electroluminescent element obtained in the example 2, because moving of pollutant from the first electrode and the light scattering layer is restrained by the conductive layer, generation of the dark spots is suppressed.

### EXPLANATION OF REFERENCES

1 Organic electroluminescent element
2 Substrate
3 Light scattering layer
4 First electrode
5 Organic light-emitting layer
6 Second electrode
7 Recess
8 Resin composition
10 Conductive layer

1-12. (canceled)

13. An organic electroluminescent element comprising, a light transmissive substrate, a first electrode, an organic light-emitting layer, and a second electrode which are stacked in this order,
the first electrode being a conductive film including conductive particles,
the organic electroluminescent element further comprising a light scattering layer between the substrate and the first electrode and in contact with the first electrode,
the light scattering layer being provided in a surface thereof with a plurality of recesses, the surface of the light scattering layer being in contact with a surface of the first electrode, and
the organic electroluminescent element further comprising a conductive layer between the first electrode and the organic light-emitting layer and in contact with the first electrode,
wherein a sheet resistance value of the conductive layer is equal to or less than that of the first electrode.

14. The organic electroluminescent element according to claim 13,
wherein a depth of each of the plurality of recesses falls within a range of 0.3 to 3.0 μm and an average value of widths of the plurality of recesses falls within a range 0.3 to 3.0 μm.

15. The organic electroluminescent element according to claim 13, wherein the first electrode has an uneven surface on an opposite side of the first electrode from the light scattering layer.

16. The organic electroluminescent element according to claim 13, wherein the first electrode contains at least one component selected from a conductive inorganic oxide, a metallic nano-material, and a conductive polymer, the conductive layer containing a conductive inorganic oxide.

17. The organic electroluminescent element according to claim 13, wherein the first electrode and the conductive layer contain a common material.

18. A lighting fixture comprising the organic electroluminescent element according to claim 13, and a housing holding the organic electroluminescent element.

19. A method of preparing an organic electroluminescent element,
the organic electroluminescent element comprising a light transmissive substrate, a first electrode, an organic light-emitting layer, and a second electrode which are stacked in this order, and
the organic electroluminescent element further comprising a light scattering layer between the substrate and the first electrode and in contact with the first electrode,
the method comprising:
a process of forming the light scattering layer,
by molding an ultraviolet curable resin composition into a film,
then forming a plurality of recesses in the resin composition by embossing the resin composition, and
then curing the resin composition by an irradiation of ultraviolet rays; and
a process of forming the first electrode,
by applying a conductive material on a surface of the light scattering layer in which a plurality of recesses are formed, and
then by curing the light scattering layer,
the method further comprising a process of forming a conductive layer on the first electrode by a vapor deposition,
wherein a sheet resistance value of the conductive layer is equal to or less than that of the first electrode.

20. A method of preparing the organic electroluminescent element according to claim 19, further comprising heating the conductive layer by an induction heating method.

21. A method of preparing the organic electroluminescent element according to claim 19, further comprising forming the conductive layer by sputtering.

22. A method of preparing the organic electroluminescent element according to claim 19, wherein the conductive material includes conductive particles.
